(19) United States
(12) Patent Application Publication
(10) Pub. No.: US 2010/0120211 A1
(43) Pub. Date: May 13, 2010

(54) Methods of manufacturing Semiconductor Devices Including PMOS and NMOS Transistors Having Different Gate Structures

(76) Inventors: Jae-Hwa Park, Yongin-si (KR); Gil-Heyun Choi, Seoul (KR); Hee-Sook Park, Seoul (KR); Jong-Min Baek, Suwon-si (KR)

Correspondence Address: MYERS BIGEL SIBLEY & SAJOVEC, PO BOX 37428, RALEIGH, NC, 27627, US

(21) Appl. No.: 12/613,746

(22) Filed: Nov. 6, 2009

(30) Foreign Application Priority Data
Nov. 7, 2008 (KR) 10-2008-0110148

(51) Int. Cl. H01L 21/8238

(52) U.S. Cl. 438/229; 257/E21.632

(57) ABSTRACT

A semiconductor device may include a semiconductor substrate having first and second regions. A first gate structure on the first region of the semiconductor substrate may include a metal oxide dielectric layer on the first region of the semiconductor substrate and a first conductive layer on the metal oxide dielectric layer. First and second source/drain regions of a first conductivity type may be provided in the first region of the semiconductor substrate on opposite sides of the first gate structure. A second gate structure on the second region of the semiconductor substrate may include a silicon oxide based dielectric layer and a second conductive layer on the silicon oxide based dielectric layer. First and second source/drain regions of a second conductivity type may be provided in the second region of the semiconductor substrate on opposite sides of the second gate structure, wherein the first and second conductivity types are different. Related methods are also discussed.

### CROSS REFERENCE TO RELATED APPLICATION

This application claims priority under 35 USC §119 to Korean Patent Application No. 10-2008-0110148, filed on Nov. 7, 2008 in the Korean Intellectual Property Office (KIPO), the disclosure of which is herein incorporated by reference in its entirety.

### BACKGROUND

1. Field

The present invention relates to semiconductor devices including dual gates and methods of manufacturing the same.

2. Description of the Related Art

Metal oxide semiconductor (MOS) transistors may be classified as N-type MOS (NMOS) transistors and P-type MOS (PMOS) transistors according to the channels. Complementary MOS (CMOS) transistors include NMOS and PMOS transistors on a single semiconductor substrate.

Silicon oxide has been widely used for the manufacture of gate insulation layers of MOS transistors. However, as sizes of semiconductor devices are reduced, thicknesses of gate insulation layers also have been reduced and an increase of leakage current at the gate insulation layer formed using the silicon oxide may occur. Accordingly, gate insulation layers using high dielectric metal oxide instead of using silicon oxide are of interest.

However, when the gate insulation layer is formed using the high dielectric metal oxide, application of polysilicon as a gate electrode may become difficult. Once the polysilicon is used to form the gate electrode, a threshold voltage may be increased due to a Fermi level pinning phenomenon caused by a bonding between metal and silicon. Then, a depletion layer may be formed between the gate electrode and the gate insulation layer to increase an equivalent oxide thickness (EOT) of a transistor, thereby reducing a driving current of the transistor.

Depletion effects of a polysilicon gate electrode and Fermi level pinning may be more serious for PMOS transistors. Particularly, boron ions doped in the polysilicon may diffuse toward the semiconductor substrate to change a flat band voltage and a threshold voltage.

Accordingly, further development of semiconductor devices including PMOS transistors using high dielectric metal oxides may be desired.

### SUMMARY

Some embodiments of the present invention relate to semiconductor devices including PMOS transistors including metal oxide and related methods of fabrication.

According to some embodiments of the present invention, a semiconductor device may include a first gate structure on a substrate in a first region, and a first impurity region doped with p-type impurities at a first portion of the substrate adjacent to the first gate structure. A second gate structure may be on the substrate in a second region, and a second impurity region may be doped with n-type impurities at a second portion of the substrate adjacent to the second gate structure. The first gate structure may include a first silicon oxide-based insulation layer, a metal oxide pattern, a metal-containing conductive pattern and a first conductive pattern. The second gate structure may include a second silicon oxide-based insulation layer and a second conductive pattern.

The first and second conductive patterns may include polysilicon. A portion of the second gate structure may be one of a gate structure of a recess channel array transistor, a gate structure of a planar transistor and/or a gate structure of a fin transistor. The second silicon oxide layer may include silicon oxide obtained through a selective thermal oxidation of the substrate.

A portion of the substrate of the second region may include third gate structures including a metal oxide pattern, a metal-containing conductive pattern and a third conductive pattern.

According to other embodiments of the present invention, a method of manufacturing a semiconductor device may include forming a first insulation layer, a preliminary metal oxide pattern and a preliminary metal-containing conductive pattern sequentially on a first region of a substrate. A second insulation layer may be formed on a second region of the substrate. A conductive layer may be formed on the preliminary metal-containing conductive pattern of the first region and the second insulation layer of the second region. The conductive layer, the preliminary metal-containing conductive pattern and the preliminary metal oxide pattern may be sequentially patterned to form a first gate structure including the first insulation layer, a metal oxide pattern, a metal-containing conductive pattern and a first conductive layer pattern on the substrate in the first region and a second gate structure including the second insulation layer and a second conductive layer pattern on the substrate in the second region. P-type impurities may be doped into a first portion of the substrate adjacent to the first gate structure in the first region to form a first impurity region, and n-type impurities may be doped into a second portion of the substrate adjacent to the second gate structure in the second region to form a second impurity region.

Sequentially forming the first insulation layer, the preliminary metal oxide pattern, and the preliminary metal-containing conductive pattern on the substrate in the first region may include forming a preliminary insulation layer on the substrate in the first and the second regions. A metal oxide layer and a metal-containing conductive layer may be sequentially formed on the preliminary insulation layer. A mask pattern may be formed in the first region to cover the metal-containing conductive layer in the first region. The metal-containing conductive layer, the metal oxide layer and the preliminary insulation layer may be selectively removed from the second region to expose the substrate in the second region.

The second insulation layer may be formed on the substrate in the second region by performing an oxidation process after selectively removing the metal-containing conductive layer, the metal oxide layer and the preliminary insulation layer from the second region. The second insulation layer may be formed by performing an oxidation process in which a surface of the substrate is selectively oxidized while suppressing oxidation of a metal component in the metal-containing conductive layer of the first region. The oxidation process may be performed under an atmosphere including hydrogen gas and an oxidizing gas such that oxidation of a metal component of the metal-containing conductive layer may be suppressed due to reductive action of hydrogen gas. The oxidizing gas may be oxygen (O₂), ozone (O₃), nitrogen oxide (NO), nitrous oxide (N₂O) or combinations thereof.

A portion of the preliminary insulation layer formed in the first region may be partially removed to expose a portion of the substrate in the first region, after forming the preliminary insulation layer on the substrate in the first and the second regions. In this case, sequentially patterning the conductive layer, the preliminary metal-containing conductive pattern and the preliminary metal oxide pattern in the first region may include forming the first gate structure including the first insulation layer, the metal oxide pattern, the metal-containing conductive pattern and the first conductive layer pattern on the substrate in the first region, and forming a third gate structure including a metal oxide pattern, a metal-containing conductive pattern and a third conductive layer pattern in the first region.

A recess may be formed in a portion of the substrate of the second region before forming the second insulation layer in the second region of the substrate.

The second insulation layer may be formed on a bottom and sidewalls of the recess and a surface of the substrate in the second region, and the conductive layer may be formed on the second insulation layer in the second region to fill the recess. Patterning the conductive layer in the second region may include forming a first portion of the second gate structure in a cell region that includes the second insulation layer formed on a bottom and sidewalls of the recess and the second conductive layer pattern filling the recess, and forming a second portion of the second gate structure in a peripheral circuit region that includes the second insulation layer formed on the substrate and the second conductive layer pattern on the second insulation layer.

Forming the recess in a portion of the substrate of the second region may be performed before sequentially forming a first insulation layer, a preliminary metal oxide pattern and a preliminary metal-containing conductive pattern on a first region of a substrate. In this case, sequentially forming the first insulation layer, the preliminary metal oxide pattern and the preliminary metal-containing conductive pattern on the substrate in the first region may include forming a preliminary insulation layer on a bottom and sidewalls of the recess and the substrate in the first and the second regions, sequentially forming a metal oxide layer and a metal-containing conductive layer on the preliminary insulation layer, forming a mask pattern in the first region to cover the metal-containing conductive layer in the first region, and selectively removing the metal-containing conductive layer, the metal oxide layer and the preliminary insulation layer from the second region to expose the recess and the substrate in the second region.

The metal-containing conductive pattern may include tantalum, titanium, aluminum, silver, copper, hafnium, zirconium, manganese, nickel, palladium, platinum, iridium, rhenium, ruthenium, ruthenium oxide, titanium nitride, tantalum nitride, tungsten nitride, hafnium nitride, zirconium nitride, tantalum silicon nitride, titanium silicon nitride, and/or nickel silicide and/or combinations thereof.

According to some embodiments of the present inventions, semiconductor devices may include a PMOS transistor including a high dielectric metal oxide. The semiconductor devices may also include an NMOS transistor including silicon oxide not generating any significant attack during etching. Thus, the semiconductor devices may exhibit high quality and high reliability. Methods of manufacturing the devices may be relatively simple and productivity may be increased.

According to still other embodiments of the present invention, a semiconductor device may include a semiconductor substrate including first and second regions. A first gate structure on the first region of the semiconductor substrate may include a metal oxide dielectric layer on the first region of the semiconductor substrate and a first conductive layer on the metal oxide dielectric layer. First and second source/drain regions of a first conductivity type may be provided in the first region of the semiconductor substrate on opposite sides of the first gate structure. A second gate structure on the second region of the semiconductor substrate may include a silicon oxide based dielectric layer and a second conductive layer on the silicon oxide based dielectric layer. First and second source/drain regions of a second conductivity type may be provided in the second region of the semiconductor substrate on opposite sides of the second gate structure, wherein the first and second conductivity types are different.

According to yet other embodiments of the present invention, a method of forming a semiconductor device may include forming a first insulation layer, a metal oxide layer, and a first conductive layer on a first region of a semiconductor substrate. The first conductive layer may include a metal, the first insulation layer may be between the metal oxide layer and the semiconductor substrate, and the metal oxide layer may be between the first insulation layer and the first conductive layer. A second insulation layer may be formed on a second region of the semiconductor substrate, and a second conductive layer may be formed on the first conductive layer and on the second insulation layer with compositions of the first and second conductive layers being different. The first insulation layer, the metal oxide layer, the first conductive layer, and the second conductive layer on the first region of the semiconductor substrate may be patterned to define a first gate structure including the patterned first insulation layer, the patterned metal oxide layer, the patterned first conductive layer, and a first portion of the patterned second conductive layer on the first region of the semiconductor substrate. The second insulation layer and the second conductive layer on the second region of the semiconductor substrate may be patterned to define a second gate structure including the patterned second insulation layer and a second portion of the patterned second conductive layer. First and second source/drain regions of a first conductivity type may be formed in the first region of the semiconductor substrate on opposite sides of the first gate structure. First and second source/drain regions of a second conductivity type may be formed in the second region of the semiconductor substrate on opposite sides of the second gate structure. Moreover, the first and second conductivity types may be different.

According to more embodiments of the present invention, a method of forming a semiconductor device may include forming a first gate structure on a first region of a semiconductor substrate with the first gate structure including a metal oxide dielectric layer on the first region of the semiconductor substrate and a first conductive layer on the metal oxide dielectric layer. A second gate structure may be formed on a second region of the semiconductor substrate with the second gate structure including a silicon oxide based dielectric layer and a second conductive layer on the silicon oxide based dielectric layer. First and second source/drain regions of a first conductivity type may be formed in the first region of the semiconductor substrate on opposite sides of the first gate structure. First and second source/drain regions of a second conductivity type may be formed in the second region of the semiconductor substrate on opposite sides of the second gate structure. Moreover, the first and second conductivity types may be different.

### BRIEF DESCRIPTION OF THE DRAWINGS

Example embodiments will be more clearly understood from the following detailed description taken in conjunction with the accompanying drawings. FIGS. 1-11 represent non-limiting, example embodiments as described herein.

FIG. 1 is a cross-sectional view illustrating a semiconductor device in accordance with some embodiments of the present invention.

FIGS. 2 to 8 are cross-sectional views illustrating operations of manufacturing a semiconductor device in FIG. 1 according to some embodiments of the present invention.

FIG. 9 is a cross-sectional view illustrating a semiconductor device in accordance with some other embodiments of the present invention.

FIG. 10 is a cross-sectional view illustrating methods of manufacturing a semiconductor device in FIG. 9 according to some embodiments of the present invention.

FIG. 11 illustrates graphs exhibiting leakage current characteristic due to stress according to an electric field for transistors of Sample 5 and Comparative Sample 3.

### DETAILED DESCRIPTION

Various example embodiments will be described more fully hereinafter with reference to the accompanying drawings, in which some example embodiments are shown. Example embodiments may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, e.g., “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms including technical and scientific terms used herein have the same meaning as commonly understood by one of ordinary skill in the art to which example embodiments belongs. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

FIG. 1 is a cross-sectional view illustrating a semiconductor device in accordance with some embodiments of the present invention.

Referring to FIG. 1, a semiconductor substrate 100 including a first region for a PMOS transistor and a second region for an NMOS transistor may be provided. The first region may correspond to a region on which the PMOS transistors may be formed in a core circuit region and/or a peripheral circuit region of a semiconductor device, and the second region may correspond to a region on which the NMOS transistors may be formed in a cell region, the core circuit region and/or the peripheral circuit region of the semiconductor device.

PMOS transistors may be provided in the first region of the semiconductor substrate 100. The PMOS transistor may include a first gate structure 126 including a first insulation layer 106a, a metal oxide pattern 108b, a metal-containing conductive pattern 110b and a first conductive pattern 120b. First, p-type impurity regions 124 may be provided on portions of the semiconductor substrate 100 adjacent to both sides of the first gate structure 126. Isolation patterns 102 may be formed on the semiconductor substrate 100 to separate active and isolation regions.

The first insulation layer 106a may include a silicon oxide-based insulation material, e.g., silicon oxide, silicon oxynitride, etc. For example, the first insulation layer 106a may include silicon oxide formed through a thermal oxidation process. When the thickness of the first insulation layer 106a increases, the equivalent oxide thickness (EOT) of a gate insulation layer may be undesirably increased. Accordingly, the first insulation layer 106a may have a thin thickness in the range of about 10 Angstroms to about 50 Angstroms. Alternatively, the metal oxide pattern 108b may be formed directly on the semiconductor substrate 100 without forming the first insulation layer 106a. In this case, the EOT of the gate insulation layer may be even further reduced.

The metal oxide pattern 108b may be formed using a material having a relatively high dielectric constant compared to silicon nitride. For example, the metal oxide pattern 108b may be formed using hafnium oxide (HfO₂), zirconium oxide (ZrO₂), titanium oxide (TiO₂), tantalum oxide (Ta₂O₅), niobium oxide (Nb₂O₃), aluminum oxide (Al₂O₃), cerium oxide (Ce₂O₃), lanthanum oxide (La₂O₃), praseodymium oxide (Pr₂O₃), dysprosium oxide (Dy₂O₃), erbium oxide (Eb₂O₃), yttrium oxide (Y₂O₃), zirconium silicon oxide (ZrSiₓO_{y}), zirconium silicon oxynitride (ZrSiₓO_{y}N_{z}), hafnium silicon oxide (HfSiₓO_{y}), hafnium silicon oxynitride (HfSi₃O_{y}N_{z}), hafnium aluminum oxide (HfAlₓO_{y}), hafnium aluminum oxynitride (HfAlₓO_{y}N_{z}), aluminum silicon oxide (AlSiₓO_{y}), aluminum silicon oxynitride (AlSiₓO_{y}N_{z}), barium silicon oxide (BaSiₓO_{y}), lead silicon oxide (PbSiₓO_{y}), BST[(Bi,Sr)TiO₃], PZT[Pb(Zr,Ti)O₃], etc. The metal oxide pattern 108b may be formed using one of the above referenced materials or may be formed by combining two or more layers of the above referenced materials.

When the metal oxide pattern 108b has a thickness less than about 30 Angstroms, leakage current may increase, and when the metal oxide pattern 108b has a thickness larger than about 100 Angstroms, the EOT may undesirably increase. Accordingly, thickness of the metal oxide pattern 108b may be in the range of about 30 Angstroms to about 100 Angstroms.

The metal-containing conductive pattern 110b may be formed using a metal-containing material having a work function appropriate for the PMOS transistor. The work function for the gate electrode of the PMOS transistor may be between a mid gap and a conduction band of a semiconductor substrate. For example, the work function of the gate electrode of the PMOS transistor may be in the range about 4.6 eV to about 5.2 eV below a vacuum level. Thus, the work function of the metal-containing conductive pattern 1101) may be at least about 4.6 eV.

The metal-containing conductive pattern 110b may be formed using a material such as tantalum (Ta), titanium (Ti), aluminum (Al), silver (Ag), copper (Cu), hafnium (Hf), zirconium (Zr), manganese (Mn), nickel (Ni), palladium (Pd), platinum (Pt), beryllium (Be), iridium (Ir), tellurium (Te), rhenium (Re), ruthenium (Ru), ruthenium oxide (RuO₂), titanium nitride (TiNₓ), tantalum nitride (TaNₓ), tungsten nitride (WNₓ), hafnium nitride (HfNₓ), zirconium nitride (ZrNₓ), tantalum silicon nitride (TaSiₓN_{y}), titanium silicon nitride (TiSiₓN_{y}), nickel silicide (NiSiₓ), etc. The metal-containing conductive pattern 110b may be formed using one of the compounds. In some embodiments, the metal-containing conductive pattern 110b may be formed using titanium nitride. The metal-containing conductive pattern may function as the gate electrode even though it has a thin thickness of about 30 Angstroms. Accordingly, the metal-containing conductive pattern 110b may have a thin thickness in the range of about 30 Angstroms to about 200 Angstroms.

Different from polysilicon, the metal-containing conductive pattern 110b may not control the work function through doping impurities. Accordingly, when the metal-containing conductive pattern 110b is used as the gate electrode material contacting the metal oxide pattern 108b, problems induced when using polysilicon (such as an increase of the threshold voltage due to Fermi level pinning phenomenon, generation of a depletion layer of a gate, and/or diffusion of boron) may be reduced.

The first conductive pattern 120b may include polysilicon, and the first conductive pattern 120b may not significantly determine the work function of the gate electrode. The first conductive pattern 120b may facilitate patterning of the metal-containing conductive pattern 110b provided as the gate electrode and function as a wiring connected to the metal-containing conductive pattern 110b. The first conductive pattern 120b may be formed using polysilicon. According to other embodiments, the first conductive pattern 120b may have an integrated structure of polysilicon and a metallic material. The metallic material for the first conductive pattern 120b may include tungsten (W), tungsten nitride (WNₓ) or tungsten silicide (WSiₓ), etc. In other embodiments, the first conductive pattern 120b may be an integrated structure of W/TiNₓ/WSiₓ. The inclusion of the metallic material in the first conductive pattern 120b may reduce a wiring resistance connected to the gate electrode.

NMOS transistors may be provided in the second region of the semiconductor substrate 100. The NMOS transistors may include a second gate structure 128 including a second insulation layer 116 and a second conductive pattern 120a. At both sides of the second gate structure 128, second impurity regions 122 of n-type impurities may be formed in the second region of the substrate.

The second insulation layer 116 may be formed through an oxidation process different from the process of forming the first insulation layer 106a. Accordingly, the first and second insulation layers 106a and 116 may have different thicknesses. The second insulation layer 116 may include silicon oxide obtained using a selective thermal oxidation of the substrate, and may optionally include nitrogen as an additional component. In some embodiments, the second insulation layer 116 may be silicon oxide obtained using an oxidation process under an atmosphere including hydrogen gas and an oxidizing gas.

The second conductive pattern 120a may include the same conductive material and the same integration structure as the first conductive pattern 120b. In some embodiments, the second conductive pattern 120a may include polysilicon and the polysilicon may be doped with n-type impurities. The second conductive pattern 120a may be provided as the gate electrode of the NMOS transistor. The work function of the gate electrode of the NMOS transistor may be determined by the doped impurities in the polysilicon. The second conductive pattern 120a may be formed using only polysilicon as the first conductive pattern 120b. Otherwise, the second conductive pattern may include an integrated structure of polysilicon and the metallic material.

NMOS transistors formed in the second region may have various structures. NMOS transistors formed in the cell region may have a gate structure of a recess channel array transistor as illustrated in FIG. 1. More particularly, the second gate structure 128 formed in the cell region may include a second insulation layer 116 on an inner surface (i.e., a bottom and sidewalls) of a recess 104 formed on the substrate. The second conductive pattern 120a may be formed while filling the recess 104. In addition, the NMOS transistor provided in the core/peripheral circuit region may include a gate structure of a planar transistor. The NMOS transistor provided in the cell region may include a gate structure of the planar transistor or a gate structure of a fin-type field effect transistor (FinFET).

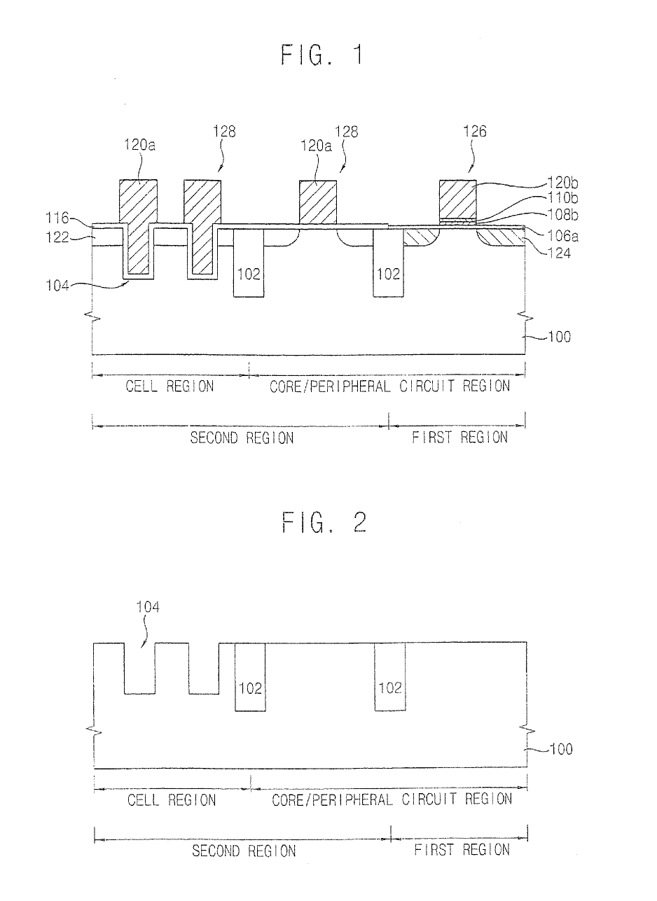

FIGS. 2 to 8 are cross-sectional views illustrating operations of manufacturing the semiconductor device in FIG. 1.

Referring to FIG. 2, a semiconductor substrate 100 including substantially single crystalline silicon may be prepared. A first region for forming PMOS transistors and a second region for forming NMOS transistors may be defined in the semiconductor substrate 100. The first region may be a PMOS transistor forming region in a core/peripheral circuit region of a semiconductor device and the second region may be an NMOS transistor forming region in a cell region and in the core/peripheral circuit region of the semiconductor device.

Isolation patterns 102 may be formed to separate active regions in the semiconductor substrate 100. The isolation patterns 102 may be provided using a shallow trench isolation process.

In some embodiments, a transistor formed in the cell region of the semiconductor device may have a recess channel transistor structure. Accordingly, a portion (s) of semiconductor substrate in the cell region, where a gate(s) of a transistor(s) is to be formed, may be selectively etched to form a recess(es) 104.

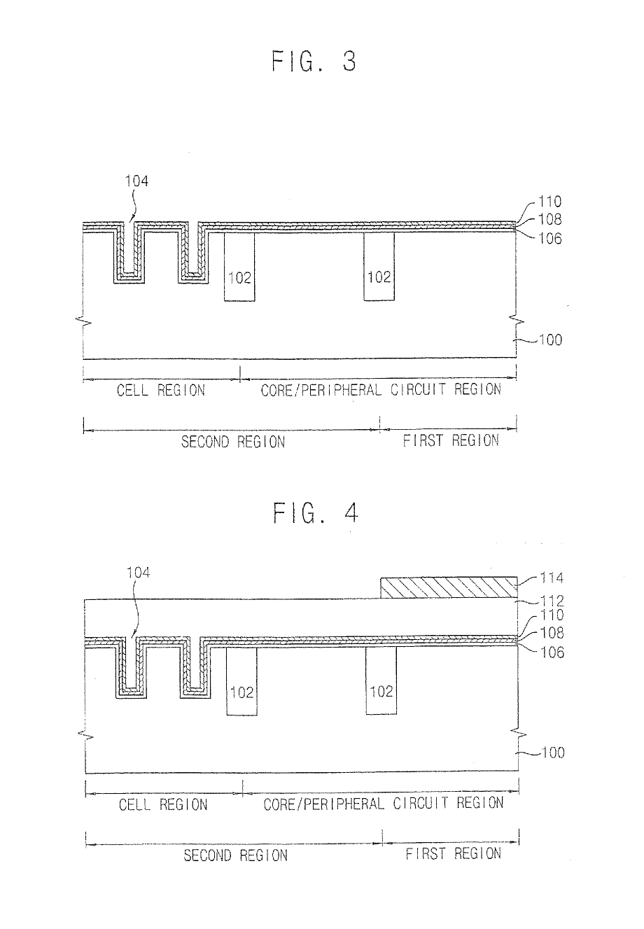

Referring to FIG. 3, a preliminary insulation layer 106 may be formed on an entire surface of the semiconductor substrate 100. The preliminary insulation layer 106 may be formed using a thermal oxidation process.

A metal oxide layer 108 having a relatively high dielectric constant may be formed on the preliminary insulation layer 106. The metal oxide layer 108 may be formed using atomic layer deposition (ALD). When a thickness of the metal oxide layer 108 is less than 30 Angstroms, leakage current may increase, and when the thickness of the metal oxide layer 108 exceeds 100 Angstroms, an BUT may undesirably increase. Accordingly, in some embodiments, a thickness of the metal oxide layer 108 may be in the range of about 30 Angstroms to about 100 Angstroms. In other embodiments, a thickness of the metal oxide layer 108 may be in the range of about 30 Angstroms to about 50 Angstroms.

The metal oxide layer 108 may be formed using a material such as hafnium oxide (HfO₂), zirconium oxide (ZrO₂), titanium oxide (TiO₂), tantalum oxide (Ta₂O₅), niobium oxide (Nb₂O₃), aluminum oxide (Al₂O₃), cerium oxide (Ce₂O₃), lanthanum oxide (La₂O₃), praseodymium oxide (Pr₂O₃), dysprosium oxide (Dy₂O₃), erbium oxide (Eb₂O₃), yttrium oxide (Y₂O₃), zirconium silicon oxide (ZrSiₓO_{y}), zirconium silicon oxynitride (ZrSiₓO_{y}N_{z}), hafnium silicon oxide (HfSiₓO_{y}), hafnium silicon oxynitride (HfSiₓO_{y}N_{z}), hafnium aluminum oxide (HfAlₓO_{y}), hafnium aluminum oxynitride (HfAlₓO_{y}N_{z}), aluminum silicon oxide (AlSiₓO_{y}), aluminum silicon oxynitride (AlSiₓO_{y}N_{z}), barium silicon oxide (BaSiₓO_{y}), lead silicon oxide (PbSiₓO_{y}), BST[(Bi,Sr)TiO₃], PZT[Pb(Zr,Ti)O₃], etc. The metal oxide layer 108 may be formed using one of the above referenced materials or may be formed by combining two or more layers of the above referenced materials.

A metal-containing conductive layer 110 may be formed on the metal oxide layer 108. The metal-containing conductive layer 110 may be obtained by depositing a metal material having a work function appropriate for a PMOS transistor. The metal-containing conductive layer 110 may be formed using a material such as tantalum (Ta), titanium (Ti), aluminum (Al), silver (Ag), copper (Cu), hafnium (Hf), zirconium (Zr), manganese (Mn), nickel (Ni), palladium (Pd), platinum (Pt), beryllium (Be), iridium (Ir), tellurium (Te), rhenium (Re), ruthenium (Ru), ruthenium oxide (RuO₂), titanium nitride (TiNₓ), tantalum nitride (TaNₓ), tungsten nitride (WNₓ), hafnium nitride (HfNₓ), zirconium nitride (ZrNₓ), tantalum silicon nitride (TaSiₓN_{y}), titanium silicon nitride (TiSiₓN_{y}), nickel silicide (NiSiₓ), etc. The metal-containing conductive layer 110 may be formed using one of the above referenced compounds. The metal-containing conductive layer 110 may not function properly as the gate electrode with a thickness of less than about 30 Angstroms. Accordingly, the metal-containing conductive layer 110 may be formed to have a thickness in the range of about 30 Angstroms to about 200 Angstroms.

Referring to FIG. 4, a first hard mask layer 112 may be formed on the metal-containing conductive layer 110. The first hard mask layer 112 may be formed using a material having a high etching selectivity with respect to both the metal-containing conductive layer 110 and the metal oxide layer 108. In some embodiments, the first hard mask layer 112 may be formed using silicon oxide. A second hard mask pattern 114 may be formed on the first hard mask layer 112 in the first region to selectively cover portions of the substrate 100.

In FIG. 4, the first hard mask layer 112 and the second hard mask pattern 114 are integrated. Otherwise, only one hard mask may be selectively provided on the metal-containing conductive layer 110 and subsequent procedures may be applied.

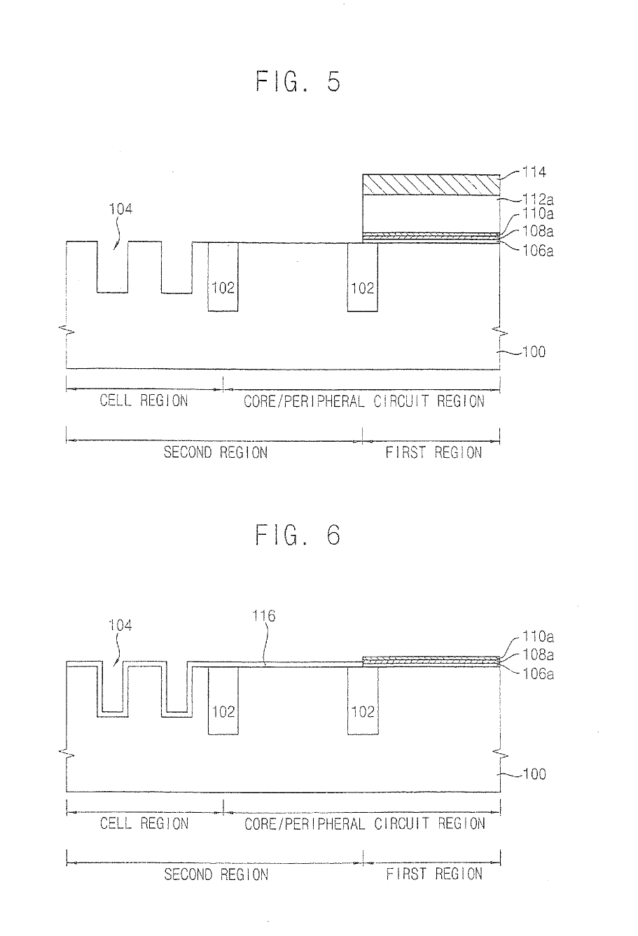

Referring to FIG. 5, the first hard mask layer 112 may be etched using the second hard mask pattern 114 to form a first hard mask pattern 112a. The metal-containing conductive layer 110, the metal oxide layer 108 and the preliminary insulation layer 106 provided on the substrate of the second region may be selectively etched using the first and second hard mask patterns 112a and 114 to form a preliminary metal-containing conductive pattern 110a, a preliminary metal oxide pattern 108a and a first insulation layer 106a. After completing the etching process, a surface of the semiconductor substrate 100 at the second region may be exposed. In this case, the etching process may be a wet etching process so that the surface of the semiconductor substrate 100 in the second region may not be significantly damaged.

Since the first and second hard mask patterns 112a and 114 are provided on the first region of the semiconductor substrate 100 after performing the etching process, the preliminary metal oxide pattern 108a and the preliminary metal-containing conductive pattern 110a may not be significantly attacked.

Accordingly, an integrated structure of the first insulation layer 106a, the preliminary metal oxide pattern 108a and the preliminary metal pattern 110a may be provided only on portions of the semiconductor substrate 100 in the first region.

Referring to FIG. 6, a second insulation layer 116 may be formed on the surface of the semiconductor substrate 100 in the second region. The exposed surface of the semiconductor substrate 100 in the second region may be selectively oxidized to form the second insulation layer 116. In this case, the exposed surface of the preliminary metal pattern 110a in the first region should not be significantly oxidized.

In particular, the selective oxidation process may be performed in an atmosphere including hydrogen gas and an oxidizing gas. The hydrogen gas may cause a reducing reaction of metal to restrain oxidation of the surface portion of the preliminary metal-containing conductive pattern 110a.

The selective oxidation process may be a thermal processing method or a plasma processing method. A thermal processing method may include a thermal furnace processing method and a metal thermal processing method. According to a thermal processing method, the oxidation may be implemented at the temperature in the range of about 850 degrees C. to about 1050 degrees C. An inflow of the hydrogen gas may be about 75 percent to about 99 percent, and the remaining inflow may be the oxidant including an oxygen atom(s). The oxidizing gas may include at least one of oxygen (O₂), ozone (O₃), nitrogen oxide (NO) and nitrous oxide (N₂O). To increase oxidation selectivity with respect to the metal, nitrogen (N₂), ammonia (NH₃), etc. may be used.

Oxidation by a plasma processing method may be performed at a temperature in the range of about 20 degrees C. to about 700 degrees C. An inflow of hydrogen gas may be in the range of about 50 percent to about 99 percent, and the remaining inflow may be the oxidant. The oxidizing gas may include at least one of oxygen (O₂), ozone (O₃), nitrogen oxide (NO), and/or nitrous oxide (N₂O). To increase an oxidation selectivity with respect to the metal, nitrogen (N₂), ammonia (NH₃), etc. may be used.

As illustrated in FIG. 6, the second insulation layer 116 may be formed on the surface of the recess 104 and on the semiconductor substrate 100 in the cell region.

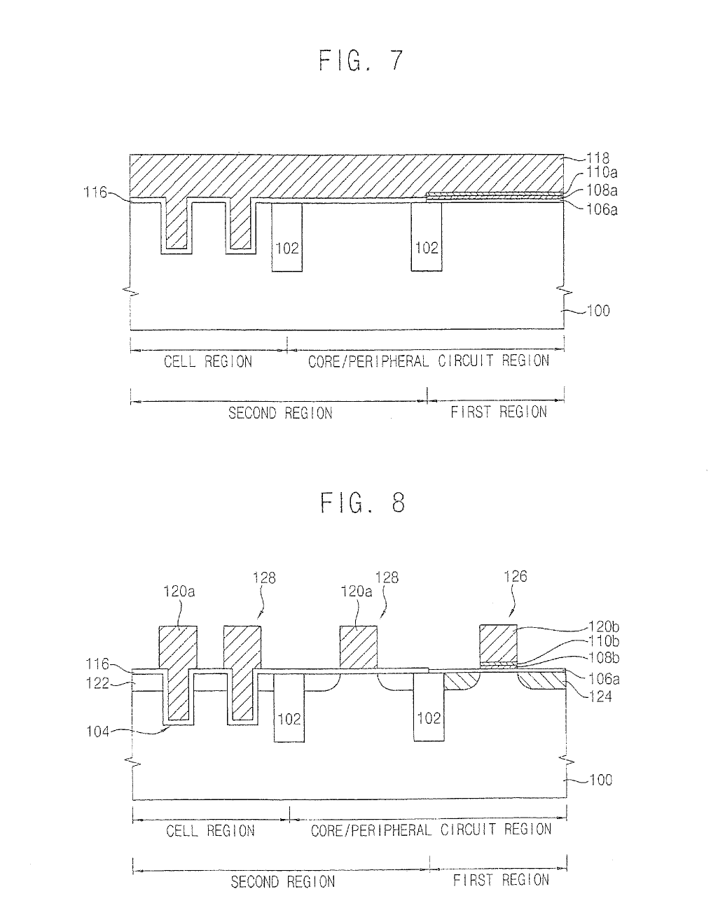

Referring to FIG. 7, a polysilicon layer 118 may be formed on the second insulation layer 116 and on the preliminary metal oxide pattern 110a. The polysilicon layer 118 may sufficiently fill the recess 104 in the cell region.

Portions of polysilicon layer 118 at the second region may be used as a gate electrode of an NMOS transistor. Accordingly, n-type impurities may be doped into the polysilicon layer 118 formed in the second region. Portions of polysilicon layer 118 formed in the first region may be used only as a wiring connected to a gate electrode of a PMOS transistor. Accordingly, portions of the polysilicon layer 118 formed in the first region may be doped with either n-type impurities or p-type impurities.

In other embodiments, an upper conductive layer including a metal may be additionally deposited on the polysilicon layer 118, even though not illustrated in FIG. 7. Such an upper conductive layer may be formed using one of tungsten (W), tungsten nitride (WN) and tungsten silicide (WSiₓ) or may be obtained by integrating W/TiN/WSiₓ.

Referring to FIG. 8, the polysilicon layer 118 may be patterned to form second gate structures 128 including a second insulation layer 116 and second conductive patterns 120a in the second region. A first portion of the second gate structure may be formed in the cell region to include the second insulation layer formed on a bottom surface and sidewalls of the recess and the second conductive layer pattern filling the recess. A second portion of the second gate structure may be formed in the core/peripheral circuit region to include the second insulation layer formed on the substrate and the second conductive layer pattern on the second insulation layer. Subsequently, the preliminary metal-containing conductive pattern 110a and the preliminary metal oxide pattern 108a may be patterned to form a first gate structure 126 including the first insulation layer 106a, a metal oxide pattern 108b, a metal-containing conductive pattern 110b and a first conductive pattern 120b on the first region.

At both sides of the second gate structure 128 in the second region, n-type impurities may be doped into the substrate to form second impurity regions 122. Into the substrate at both sides of the first gate structure 126 in the first region, p-type impurities may be doped to form first impurity regions 124.

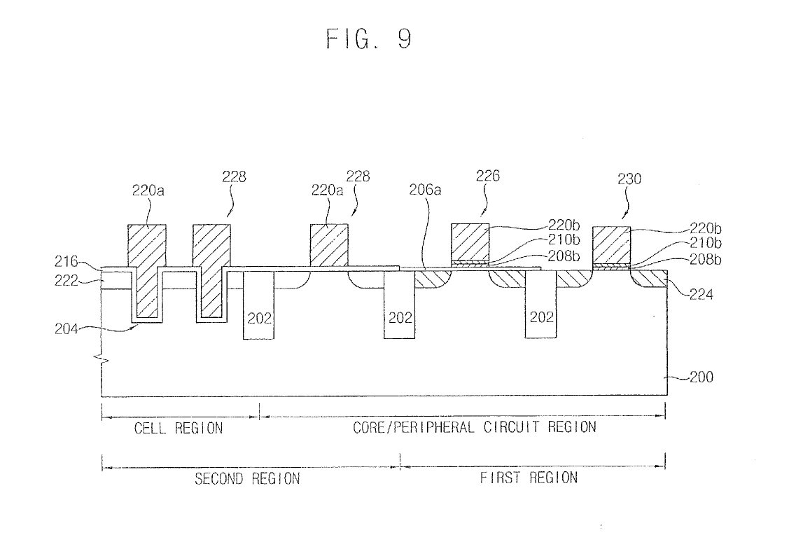

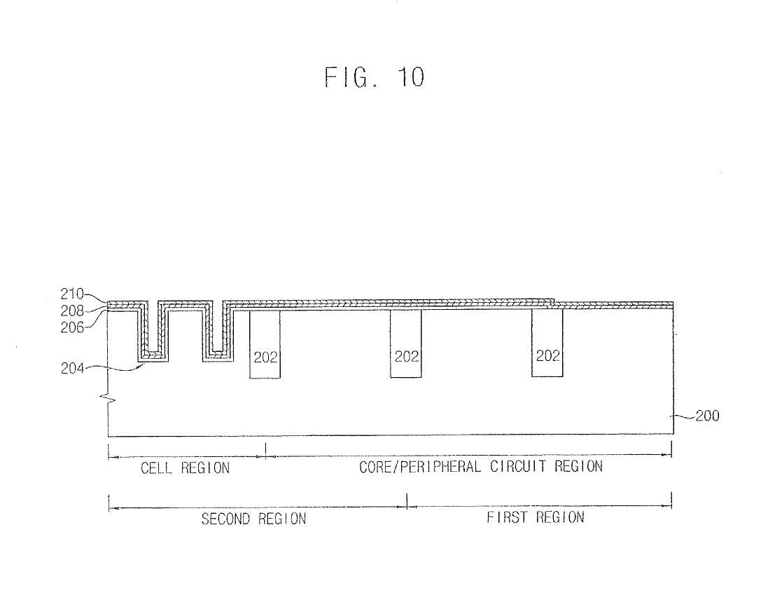

FIG. 9 is a cross-sectional view illustrating a semiconductor device according to other embodiments of the present invention.

Referring to FIG. 9, a semiconductor device may include PMOS transistors on a first region of substrate 200. A first portion of the PMOS transistors may include a first gate structure 226 including a first insulation layer 206a, a metal oxide pattern 208b, a metal-containing conductive pattern 210b and a first conductive pattern 220b. A second portion of the PMOS transistors may include a third gate structure 230 including a metal oxide pattern 208b, a metal pattern 210b and a third conductive pattern 220b.

P-type impurity doped first impurity regions 224 may be provided at both sides of the first and third gate structures 226 and 230 on the substrate in the first region.

The semiconductor substrate 200 may include NMOS transistors at the second region. The NMOS transistors may include a second gate structure 228 including a second insulation layer 216 and a second conductive pattern 220a. N-type impurity doped second impurity regions 222 may be provided at both sides of the second gate structure 228 on the substrate in the second region. Isolation patterns 202 may be provided on the semiconductor substrate 200 to separate active regions. The NMOS transistors provided in the second region may have the same structures as described in Example 1.

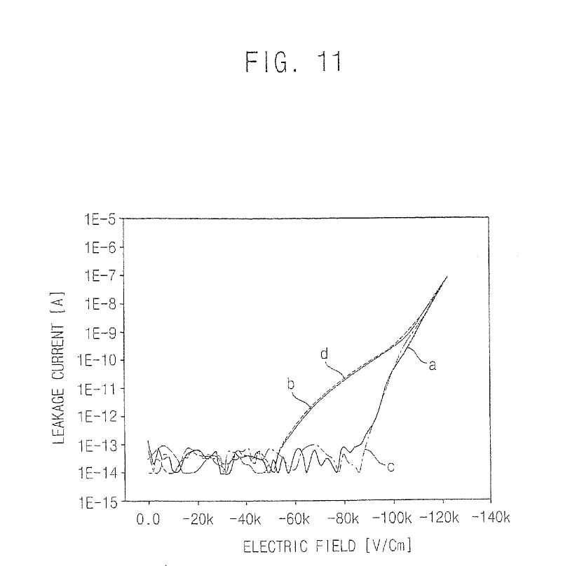

FIG. 10 is a cross-sectional view illustrating methods of manufacturing the semiconductor device in FIG. 9.

First, the isolation patterns 202 may be formed on the semiconductor substrate according to the method described referring to FIG. 2.

Referring to FIG. 10, the semiconductor substrate 200 may include the isolation patterns 202 and recesses 204. The recess 204 may be formed by selectively etching portions of the substrate on which a gate of an NMOS transistor may be formed. An insulation layer (e.g., a silicon oxide layer or a silicon oxynitride layer) may be formed on the entire surface of the semiconductor substrate 200. For example, a silicon oxide layer may be formed using a thermal oxidation process. A portion of the insulation layer in the first region may be removed to form a preliminary insulation layer 206 on the substrate 200. A metal oxide layer 208 having a relatively high dielectric constant may be formed on the preliminary insulation layer 206. The metal-containing conductive layer 210 may be formed on the metal oxide layer 208.

After that, the semiconductor device illustrated in FIG. 9 may be manufactured using processes described referring to FIGS. 4 to 8.

A gate insulation layer of an NMOS transistor of semiconductor devices according to some embodiments may be formed using silicon oxide obtained using a selective oxidation process. However, when performing a common oxidation process to form the gate insulation layer of the NMOS transistor, metal oxide material may be formed on a metal-containing conductive layer in a first region thereby increasing resistance. In this case, the metal-containing conductive layer and the first conductive pattern may be insulated from each other and performance may be reduced. However, according to some embodiments, the metal oxide material may not be formed when performing the selective oxidation process so that a resistance of the metal-containing conductive layer formed in the first region may not be increased.

Resistances of a metal-containing conductive layer after performing the selective oxidation process according to some embodiments and resistances of a metal-containing conductive layer after performing a common thermal radical oxidation process are compared hereinafter.

Experiment 1

Preparation of Sample 1

A tungsten layer was formed on a substrate. A selective plasma oxidation process was performed with respect to the tungsten layer. The oxidation process was performed with an inflow of N₂O:H₂ in a mixing ratio of about 1:3 at about 800 degrees C.

Preparation of Sample 2

A tungsten layer was formed on a substrate. A selective plasma oxidation process was performed with respect to the tungsten layer. The oxidation process was performed with an inflow of N₂O:H₂ in a mixing ratio of about 1:8 at about 800 degrees C.

Preparation of Comparative Sample 1

A tungsten layer was formed on a substrate. A selective plasma oxidation process was performed with respect to the tungsten layer. The oxidation process was performed with an inflow of N₂O at about 800 degrees C.

Resistances of Samples 1 and 2 and Comparative Sample 1 were measured. Ratios of the resistance of each sample with respect to the resistance of each deposited tungsten layer before performing the oxidation were evaluated and illustrated in Table 1.

TABLE 1

| | | | Comparative |
|---|---|---|---|
| | Sample 1 | Sample 2 | Sample 1 |
| Sample resistance/deposited | 0.83 | 0.82 | 5000 |
| layer resistance | | | |

Experiment 2

Preparation of Sample 3

A titanium nitride layer was formed on a substrate. A selective plasma oxidation process was performed with respect to the titanium nitride layer. The oxidation process was performed with an inflowing N₂O:H₂ in a mixing ratio of about 1:3 at about 800 degrees C.

Preparation of Sample 4

A titanium nitride layer was formed on a substrate. A selective plasma oxidation process was performed with respect to the titanium nitride layer. The oxidation process was performed with inflow of N₂O:H₂ in a mixing ratio of about 1:8 at about 800 degrees C.

Preparation of Comparative Sample 2

A titanium nitride layer was formed on a substrate. A selective plasma oxidation process was performed with respect to the titanium nitride layer. The oxidation process was performed with inflow of N₂O at about 800 degrees C.

The resistances of Samples 3 and 4 and Comparative Sample 2 were measured. Ratios of the resistance of each sample with respect to the resistance measured of each deposited titanium nitride layer before performing the oxidation were evaluated and illustrated in Table 2.

TABLE 2

| | | | Comparative |
|---|---|---|---|
| | Sample 3 | Sample 4 | Sample 2 |
| Sample resistance/deposited | 0.84 | 0.81 | Immeasurable |
| layer resistance | | | |

As shown in Experiments 1 and 2, resistances of the metal-containing conductive layer of each sample among the Samples 1 to 4 obtained after performing the selective oxidation process, did not increase but rather decreased. Accordingly, a gate insulation layer may be formed at a second region without increasing the resistance of the metal-containing conductive layer in the first region by performing the selective oxidation process. On the contrary, a portion of the metal-containing conductive layer might be changed into a metal oxide layer to significantly increase the resistance by performing the common thermal radical oxidation process. Therefore, the commonly applied thermal radical oxidation process may not be applicable for the formation of the gate insulation layer of the NMOS transistor according to the some embodiments.

The gate insulation layer of the NMOS transistor may be formed using the silicon oxide obtained through the selective oxidation process on a semiconductor substrate according to some embodiments. An operational characteristic of the NMOS transistor including silicon oxide obtained using the selective oxidation process was confirmed as sufficient. Leakage current characteristics were evaluated for NMOS transistors including silicon oxide formed using the selective oxidation process.

Experiment 3

Preparation of Sample 5

A gate insulation layer was formed on a substrate using a selective plasma oxidation process. The selective plasma oxidation process was performed with inflow of O₂:H₂ in a mixing ratio of about 1:8 at about 700 degrees C. Then, a gate electrode was formed using polysilicon on the gate insulation layer and then, source/drain regions were formed. An NMOS transistor was manufactured.

Preparation of Comparative Sample 3

A gate insulation layer was formed on a substrate using a selective plasma oxidation process. The selective plasma oxidation process was performed with inflow of O₂ at about 700 degrees C. Then, a gate electrode was formed using polysilicon on the gate insulation layer and then, source/drain regions were formed. An NMOS transistor was manufactured.

FIG. 11 graphically illustrates leakage current characteristic due to a stress for a transistor of Sample 5 and a transistor of Comparative Sample 3 as a function of an electric field.

Referring to FIG. 11, graph “a” illustrates leakage current characteristic measured for a transistor of Sample 5. Graph “b” illustrates leakage current characteristic measured for a transistor of Sample 5 after applying a constant stress to the gate electrode. In particular, the leakage current characteristic was measured after applying a current of 0.1 C/cm² to the gate electrode for a constant time.

Graph “c” illustrates leakage current characteristics measured for a transistor of Comparative Sample 3. Graph d illustrates leakage current characteristics measured for a transistor of Comparative Sample 3 after applying a constant stress to a gate electrode. In particular, the leakage current characteristic was measured after applying a current of 0.1 C/cm² to the gate electrode for a constant time.

Referring to FIG. 11, leakage current characteristics after applying the stress for the Sample 5 and the Comparative Sample 3, exhibit almost no difference. The NMOS transistor including the gate insulation layer formed using the selective plasma oxidation process exhibits similar electric characteristic to that of the NMOS transistor including the gate insulation layer formed using the common thermal radical oxidation process. The gate insulation layer of the NMOS transistor formed using the selective plasma oxidation process provides excellent characteristics.

Accordingly, an NMOS transistor and a PMOS transistor having good characteristics may be respectively formed on one substrate. The semiconductor devices and methods of manufacturing the semiconductor devices may be applied in various electronic products and communication products.

The foregoing is illustrative of embodiments of the present inventions and is not to be construed as limiting thereof. Although a few examples of embodiments have been described, those skilled in the art will readily appreciate that many modifications are possible these without materially departing from the novel teachings of these embodiments. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it may be understood that the foregoing may be illustrative of various examples of embodiments and is not to be construed as limited to the specific embodiments disclosed, and that modifications to the disclosed embodiments, as well as other embodiments, are intended to be included within the

[symbol]

1-7. (canceled)

8. A method of forming a semiconductor device, the method comprising:
forming a first insulation layer, a metal oxide layer, and a first conductive layer on a first region of a semiconductor substrate, wherein the first conductive layer includes a metal, wherein the first insulation layer is between the metal oxide layer and the semiconductor substrate, and wherein the metal oxide layer is between the first insulation layer and the first conductive layer;
forming a second insulation layer on a second region of the semiconductor substrate;
forming a second conductive layer on the first conductive layer and on the second insulation layer wherein compositions of the first and second conductive layers are different;
patterning the first insulation layer, the metal oxide layer, the first conductive layer, and the second conductive layer on the first region of the semiconductor substrate to define a first gate structure including the patterned first insulation layer, the patterned metal oxide layer, the patterned first conductive layer, and a first portion of the patterned second conductive layer on the first region of the semiconductor substrate;
patterning the second insulation layer and the second conductive layer on the second region of the semiconductor substrate to define a second gate structure including the patterned second insulation layer and a second portion of the patterned second conductive layer;
forming first and second source/drain regions of a first conductivity type in the first region of the semiconductor substrate on opposite sides of the first gate structure; and
forming first and second source/drain regions of a second conductivity type in the second region of the semiconductor substrate on opposite sides of the second gate structure, wherein the first and second conductivity types are different.

9. A method according to claim 8 wherein forming the first insulation layer, the metal oxide layer, and the first conductive layer on the first region of the semiconductor substrate comprises,
forming a preliminary insulation layer on the first and second regions of the substrate,
forming a preliminary metal oxide layer on the preliminary insulation layer on the first and second regions of the semiconductor substrate,
forming a preliminary first conductive layer on the preliminary metal oxide layer on the first and second regions of the semiconductor substrate, and
selectively removing portions of the preliminary first conductive layer, the preliminary metal oxide layer, and the preliminary insulation layer from the second region of the semiconductor substrate to define the first insulation layer, the metal oxide layer, and the first conductive layer on the first region of the semiconductor substrate and to expose the second region of the semiconductor substrate.

10. A method according to claim 9, wherein forming the second insulation layer comprises,
after selectively removing portions of the preliminary first conductive layer, the preliminary metal oxide layer, and the preliminary insulation layer, thermally oxidizing the exposed second region of the semiconductor substrate.

11. A method according to claim 10 wherein thermally oxidizing the exposed second region of the semiconductor substrate comprises selectively thermally oxidizing the exposed second region of the semiconductor substrate while suppressing oxidation of the first conductive layer.

12. A method according to claim 11 selectively thermally oxidizing the exposed second region of the semiconductor substrate is performed in an atmosphere including hydrogen gas and an oxidizing gas such that oxidation of the first conductive layer is suppressed due to reductive action of the hydrogen gas.

13. A method according to claim 12 wherein the oxidizing gas comprises at least one selected from the group consisting of oxygen (O2), ozone (O3), nitrogen oxide (NO), and nitrous oxide (N2O).

14. A method according to claim 9 further comprising:
before forming the preliminary metal oxide layer, selectively removing the preliminary insulation layer from a first portion of the first region of the semiconductor substrate while maintaining the preliminary insulation layer on a second portion of the first region of the semiconductor substrate.

15. A method according to claim 14 wherein the first gate structure is on the second portion of the first region of the semiconductor substrate, the method further comprising:
patterning portions of the metal oxide layer, the first conductive layer, and the second conductive layer on the first portion of the first region of the semiconductor substrate to define a third gate structure including portions of the patterned metal oxide layer, the patterned first conductive layer, and a first portion of the patterned second conductive layer on the first portion of the first region of the semiconductor substrate;
forming third and fourth source/drain regions of the first conductivity type in the first portion of the first region of the semiconductor substrate on opposite sides of the third gate structure.

16. A method according to claim 8 further comprising:
before forming the second insulation layer, forming a recess in the second region of the semiconductor substrate, wherein the patterned second insulation layer is on a bottom surface and sidewalls of the recess, and wherein the second portion of the patterned second conductive layer is on the patterned second insulation layer opposite the bottom surface and sidewalls of the recess.

17. A method according to claim 16 wherein forming the recess comprises forming the recess in a first portion of the second region of the semiconductor substrate, the method further comprising:
patterning portions of the second insulation layer and the second conductive layer on a second portion of the second region of the semiconductor substrate to define a third gate structure including portions of the patterned second insulation layer and the patterned second conductive layer on the second portion of the second region of the semiconductor substrate;
forming third and fourth source/drain regions of the second conductivity type in the second portion of the second region of the semiconductor substrate on opposite sides of the third gate structure, wherein the second portion of the second region of the semiconductor substrate defines a planar surface.

18. A method according to claim 16 wherein forming the recess precedes forming the first insulation layer, the first metal oxide layer, and the first conductive layer.

19. A method according to claim 8 wherein the first conductive layer comprises at least one selected from the group consisting of tantalum, titanium, aluminum, silver, copper, hafnium, zirconium, manganese, nickel, palladium, platinum, iridium, rhenium, ruthenium, ruthenium oxide, titanium nitride, tantalum nitride, tungsten nitride, hafnium nitride, zirconium nitride, tantalum silicon nitride, titanium silicon nitride, and nickel silicide.

20. A method of forming a semiconductor device, the method comprising:
forming a first gate structure on a first region of a semiconductor substrate wherein the first gate structure includes a metal oxide dielectric layer on the first region of the semiconductor substrate and a first conductive layer on the metal oxide dielectric layer;
forming a second gate structure on a second region of the semiconductor substrate wherein the second gate structure includes a silicon oxide based dielectric layer and a second conductive layer on the silicon oxide based dielectric layer;
forming first and second source/drain regions of a first conductivity type in the first region of the semiconductor substrate on opposite sides of the first gate structure; and
forming first and second source/drain regions of a second conductivity type in the second region of the semiconductor substrate on opposite sides of the second gate structure [symbol]
